(19) United States
(12) Patent Application Publication
(10) Pub. No.: US 2008/0217717 A1
(43) Pub. Date: Sep. 11, 2008

(54) CTE MATCHED MULTIPLEXOR

(75) Inventors: Nicholas J. Pfister, Buellton, CA (US); Eric F. Schulte, Santa Barbara, CA (US)

Correspondence Address: BIRCH STEWART KOLASCH & BIRCH, PO BOX 747, FALLS CHURCH, VA, 22040-0747, US

(73) Assignee: LOCKHEED MARTIN CORPORATION, Bethesda, MD (US)

(21) Appl. No.: 12/043,765

(22) Filed: Mar. 6, 2008

Related U.S. Application Data
(60) Provisional application No. 60/905,798, filed on Mar. 9, 2007.

(51) Int. Cl. H01L 21/50; H01L 31/024

(52) U.S. Cl. 257/443; 438/66; 257/E21.499; 257/E31.131

(57) ABSTRACT

The invention consists of a wafer-level expansion-matched design which forces a substrate to expand and contract at the same rate as a surface-mounted component, which reduces mechanical stress on the component. An embodiment of an expansion-matched MUX design consists of two pieces of silicon sandwiching a shim, which has a higher CTE than the silicon. By modifying the silicon thickness, shim thickness, and shim material, the CTE of the composite structure may be tailored.

The composite structure is produced by a wafer level bonding approach to the balanced stack. Performing the bonding at the wafer level reduces die level touch time and improves planarity. Furthermore, a wafer level solution facilitates fabrication processes at elevated temperatures as the match occurs for both heating and cooling.

### PRIORITY

This Nonprovisional application claims priority under 35 U.S.C. § 119(e) on U.S. Provisional Application No. 60/905,798 filed on Mar. 9, 2007, the entire contents of which are hereby incorporated by reference.

### FIELD OF THE INVENTION

The present invention relates to a method an apparatus for matching coefficients of thermal expansion (CTE) for substrates with dissimilar CTE's. Specifically, the invention relates to a processing method and substrate that reduces CTE mismatch between a substrate and components attached to that substrate.

### BACKGROUND

Focal plane arrays (FPAs) are found in a wide range of industrial and military applications where detection of infrared, visible light, or even ultra-violet wavelengths is required. Typically, focal plane arrays consist of a detector array that is hybridized to a ROIC (readout integrated circuit) that allows other downstream devices to receive detection information from the FPA. Currently, there is a yield loss and a field reliability hazard due to cracks in the detector material of a focal plane array. The cracks occur predominately within the first five thermal cycles; however, there are also latent failures that occur in dewar build or in the field. The root cause of this cracking is a CTE mismatch between a detector material, such as Indium Antimonide (InSb), and the underlying silicon readout Integrated Circuit (IC). The integrated average CTE of Si is 1.22 ppm/K, while InSb has a CTE of 4.38 ppm/K. This CTE mismatch causes the InSb to be placed in tension while cooling. If there are any defects in the InSb such as edge chips, crystal defects, etc., a crack along a crystalline plane can be easily generated.

There are currently two approaches to reducing the expansion mismatch of the detector material and the readout IC material. The first method involves bonding a very thin readout IC to a thick piece of shim material, which has a CTE very close to the detector material. As a result, the readout IC is essentially slaved to the thicker shim material and is forced to expand/contract at the same rate as the shim material. The second approach is the balanced stack; however, this sandwich structure is generally bonded at the die level. This involves much more touch time per focal plane array (FPA) because it is not a wafer level bonding approach, which in turn increases the prospect of defects and contamination introduced during the extra processing. In both approaches, the prior art is specifically restricted to detectors fabricated with transparent substrates.

### SUMMARY

The invention consists of a wafer-level expansion-matched design which forces a substrate to expand and contract at the same rate as a surface-mounted component, which reduces mechanical stress on the component. An embodiment of a wafer-level expansion-matched MUX design forces the MUX to expand and contract at the same rate as an InSb detector, reducing mechanical stress and decreasing the propensity for the detector to crack. The expansion-matched MUX design consists of two pieces of silicon sandwiching a shim, which has a higher CTE than the silicon. By modifying the silicon thickness, shim thickness, and shim material, the CTE of the composite structure may be tailored. Alternative embodiments of the present invention may be tailored in both thickness and overall material composition for a variety of applications and surface-mounted modules.

The inventive solution also comprises a wafer level bonding approach to the balanced stack. The balanced stack allows one to tailor the CTE of a silicon readout IC without inducing a bending moment, because the stack is balanced. Previously, the bonding of this stack has been performed at the die level post hybridization. Performing the bonding at the wafer level pre hybridization reduces die level touch time and improves planarity. Furthermore, a wafer level solution enables readout to die hybridization, or other production or fabrication processes, at elevated temperatures as the match occurs for both heating and cooling.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### DRAWINGS

The present invention will become more fully understood from the detailed description given hereinbelow and the accompanying drawing which is given by way of illustration only, and thus is not limitative of the present invention, and wherein:

FIG. 1 shows the build-up of a balanced wafer stack, the attachment of components, and the separation of the wafer into individual pieces; and

FIG. 2 shows an embodiment of a process for manufacturing a balanced wafer stack according to the present invention.

The drawings will be described in detail in the course of the detailed description of the invention.

### DETAILED DESCRIPTION

The following detailed description of the invention refers to the accompanying drawings. The same reference numbers in different drawings identify the same or similar elements. Also, the following detailed description does not limit the invention. Instead, the scope of the invention is defined by the appended claims and equivalents thereof.

In order to avoid the extra processing time, and its associated costs and problems, involved in bonding a balanced stack between a detector array and its underlying readout integrated circuit (ROIC), a new method is proposed that employs wafer-level bonding before hybridization.

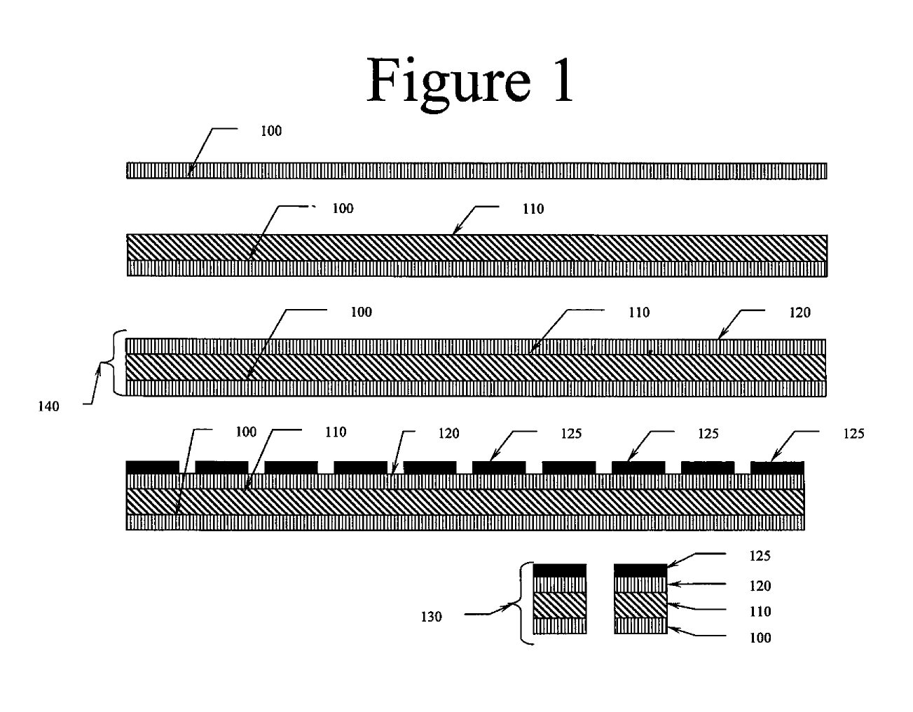

Wafer-level bonding allows for the building of a balanced stack at the wafer level—before the individual modules are cut apart. This drastically reduces handling time and also allows for the creation of a CTE-matched ROIC to attach the detector instead of bonding the detector to the ROIC and then compensating for CTE after bonding. Also, bonding at the wafer level allows for a single wafer-level bonding process instead of requiring individual processing for the CTE-matching of each module cut from the wafer. An embodiment of a balanced stack according to the present invention is shown in FIG. 1.

In one embodiment of the balanced stack, the CTE structure consists of a two silicon substrates 100, 120 that sandwich a Y2O3 (yttria) stabilized zirconia wafer 110. The top silicon substrate 120 contains the ROIC circuitry, while the bottom silicon 100 substrate is blank. All three of the substrates are bonded together simultaneously using a cryogenic grade epoxy. The bonding process takes place inside a bonding press, which consists of two heated plates that are extremely flat. Epoxy is applied to each wafer and the stack 140 is placed between the plates and heated to a curing temperature of 85 C for 4 hours. The bondline is controlled with glass beads that have a diameter of nominally 0.001.″ One embodiment of a balanced stack 140 designed to match the CTE of InSb, sets both Si substrates at 0.008″ thick and the zirconia at 0.0118″ thick. Each epoxy bondline in this embodiment is 0.001″ thick.

In other embodiments of the present invention, the shim layer 110, depending on the desired thickness, can be vapor-deposited, plated, or soldered onto the silicon wafers 100, 120. The substrate wafers can be soldered to the shim layer in a manner that precludes either shim or solder reflow during later processing. The shim layer, in addition to controlling the CTE, can act as a heat-spreader or internal heat-sink. This further reduces CTE-matching issues by reducing the overall heat load on the eventual device.

In the present invention, the bonding of the balanced stack layers takes place before the wafer is diced into individual die components. In one embodiment of the present invention, the CTE matched die goes through a standard surface component mount process as any other die component would, so there is no change in any further processing.

In one embodiment of the present invention, after the stack 140 is cut into dies, the detector array 125 is attached to the ROIC circuitry on the top silicon substrate 120 to create the FPA component 130. This embodiment of the invention does not require the detector 125 to be disposed on a transparent substrate.

This approach is not limited to FPA devices and ROICs. This approach can be used for any component that would benefit from modifying its CTE. In addition, this approach can be performed at the wafer level so CTE “modifying/tailoring” can be performed on many components simultaneously before they are diced into individual dies or modules. It is a suitable fabrication technique for any component combination where there is a CTE mismatch between various materials that have dissimilar CTEs. It is also suitable for heat-generating components such as RF components and similar devices where having a metal shim layer provides heat-spreading as well as CTE matching. Further, alternative embodiments of this approach may use non-metal shim layers, such as ceramics or fiberglass, where the CTE mismatch is due to components that have a CTE lower than that of Si.

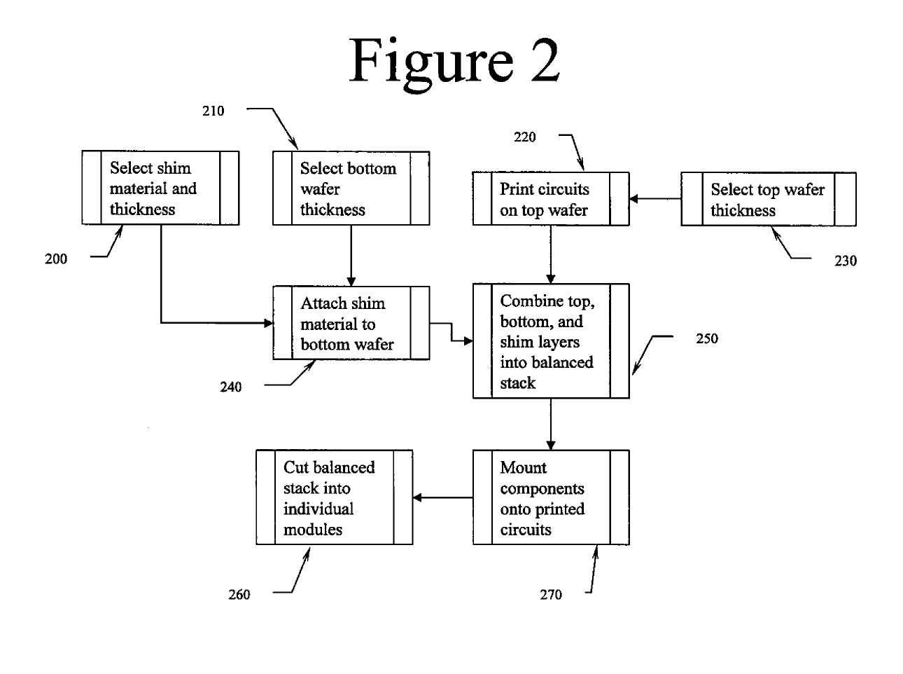

An embodiment of the fabrication process required to produce an embodiment of the inventive apparatus is described in FIG. 2. The selection of the shim material and thickness 200, bottom wafer material and thickness 210, and top wafer material and thickness 220 are relatively independent, though inter-connected, procedures that affect each-other, but are not temporally restricted to a particular order. In one embodiment of the present invention, the top wafer material is selected as silicon 220, the ROIC is fabricated on the top silicon wafer 230, then the wafer is thinned to the desired thickness 225. In selecting a shim material and thickness 200, thin metals may be sputtered or plated, thick metals may be soldered, and most shim materials may be attached by any of the prior methods, or also by anodic bonding, thin film deposition, epoxy or other forms of chemical adhesion. Methods of attaching the shim material depend on the type and thickness of the shim material selected.

In an embodiment of the present invention, after selecting a material and a thickness for the stack components, the wafers are combined with the shim material to form a balanced stack 250. This embodiment entails bonding all three layers together simultaneously. Bonding in multiple steps may create difficulties in keeping the structure flat, potentially resulting in an unbalanced stack.

Other embodiments may dispose the shim layer on one side of one wafer and then combine it with the other wafer, or may partially dispose the shim layer on both wafers and then combine the wafers to form a complete shim layer, and yet other embodiments may allow for the creation of the wafer stack prior to printing circuits on the top wafer.

In one embodiment of the present invention, once the balanced stack is created, it may be cut into individual dies 260 and then have additional components mounted to the dies 270. This approach permits fabrication processes such as mounting a detector die to a CTE-matched ROIC unit to be carried out with little or no modification. The CTE-matched balanced stack die components created by this embodiment of the present invention can be further processed using existing fabrication methods and facilities.

An alternative embodiment of the invention entails mounting additional components to the balanced stack wafer before it is cut into dies. In such an embodiment where an FPA is being fabricated, each detector die could be mounted to each ROIC unit on the wafer after the ROIC wafer is CTE matched. This would result in hybridizing each detector die before dicing the “hybridized” wafer. It may also be necessary, in such an embodiment, to thin the detector dies in a bulk fashion prior to dicing. Such an approach would allow for the consolidation and simultaneous execution of multiple processing steps, and may result in fewer component failures due to CTE mismatch, and higher production yields with shorter manufacturing times.

The invention being thus described, it will be obvious that the same may be varied in many ways. Such variations are not to be regarded as departure from the spirit and scope of the invention, and all such modifications as would be obvious to one skilled in the art are intended to be included within the scope of the following claims.

What is claimed is:

1. A method of accommodating CTE mismatch in a Focal Plane Array (FPA) having a readout integrated circuit (ROIC) substrate with a first coefficient of thermal expansion (CTE) and a detector array with a second CTE, the method comprising:
printing an ROIC on a first wafer;
thinning said first wafer to a first thickness after said printing;
selecting a second wafer of a third thickness;
selecting as a shim layer a material having a second thickness and a specified CTE;
bonding the first wafer, second wafer, and shim layer together simultaneously to form a balanced wafer stack having a specified composite average CTE, wherein the composite average CTE is determined by the relative thicknesses of the wafers and the shim layer, and also by the composition of the shim layer, and wherein the shim layer is disposed between the wafers;
dicing the wafer stack into individual dies, wherein each die contains one ROIC;
hybridizing the individual dies by attaching the detector array to the ROIC of a die.

2. The method of claim 1, wherein the first wafer is a silicon wafer.

3. The method of claim 1, wherein the second wafer is composed of a material having the same CTE and elastic modulus as silicon.

4. The method of claim 1, wherein the shim layer comprises a Y2O3 (yttria) stabilized zirconia wafer.

5. The method of claim 1, wherein the shim layer material comprises a metal, ceramic, polymer, metal matrix composite, cermet, or semiconductor.

6. The method of claim 1, wherein said bonding is accomplished using cryogenic-grade epoxy and a bonding press.

7. The method of claim 1, wherein said bonding is accomplished by at least one of: bonding with adhesive, fusion bonding, anodic bonding, and intermediate layer bonding.

8. The method of claim 1, wherein the detector portion of the detector array is not disposed on a transparent substrate.

9. A method of accommodating CTE mismatch in microelectronic or optoelectronic components where a module has different CTE than its immediate substrate by creating a balanced stack with a configurable composite average CTE as a substrate material, the method comprising:
selecting a first wafer of a first material and a first thickness;
selecting a second wafer of a third material and a third thickness;
selecting a shim layer of a second material and a second thickness;
bonding the first wafer, second wafer, and shim layer together to form a balanced wafer stack having a specified composite average CTE, wherein the composite average CTE is determined by the relative thicknesses of the wafers and the shim layer, and also by the compositions of the wafers and shim layer, and wherein the shim layer is disposed between the wafers;
dicing the wafer stack into individual balanced stack dies suitable for farther fabrication processing or hybridization.

10. The method of claim 9, said bonding comprising simultaneously bonding the first wafer, second wafer, and a wafer comprising said shim layer together.

11. The method of claim 9, said bonding comprising:
partially depositing said shim layer onto said first wafer;
partially depositing said shim layer onto said second wafer; and
bonding together said wafers so that the partially deposited shim material on said first wafer is bonded to the partially deposited shim material on said second wafer, thereby creating the balanced wafer stack.

12. The method of claim 9, said second material comprising a metal, ceramic, polymer, metal matrix composite, cermet, or semiconductor.

13. The method of claim 11, said depositing comprising plating, physical vapor deposition, chemical vapor deposition or soldering.

14. The method of claim 9, said bonding being accomplished by at least one of: bonding with adhesive, fusion bonding, anodic bonding, and intermediate layer bonding.

15. The method of claim 9, said first material comprising a semiconductor, ceramic, or polymer.

16. The method of claim 9, wherein the shim layer also functions as a heat-spreader.

17. The method of claim 9, said third material comprising a semiconductor, ceramic, or polymer.

18. An apparatus for accommodating CTE mismatch in a Focal Plane Array (FPA) having a readout integrated circuit (ROIC) substrate with a first coefficient of thermal expansion (CTE) and a detector array with a second CTE, the apparatus comprising:
a first wafer of a first material and a first thickness, wherein the ROIC is printed on the first wafer;
a second wafer of a second material and a third thickness;
a shim layer of a third material having a second thickness and a specified CTE;
wherein the first wafer, second wafer, and shim layer are bonded together simultaneously to form a balanced wafer stack having a specified composite average CTE, wherein the composite average CTE is determined by the relative thicknesses of the wafers and the shim layer, and also by the composition of the shim layer, and wherein the shim layer is disposed between the wafers; and
further wherein the wafer stack is diced into individual dies, wherein each die contains one ROIC; and
further wherein the individual dies are hybridized by attaching the detector array to the ROIC of a die.

19. The apparatus of claim 18, wherein the first wafer is a silicon wafer.

20. The apparatus of claim 18, wherein the second wafer is composed of a material having the same CTE and elastic modulus as silicon.

21. The apparatus of claim 18, wherein the shim layer comprises a Y2O3 (yttria) stabilized zirconia wafer.

22. The apparatus of claim 18, wherein the shim layer material comprises a metal, ceramic, polymer, metal matrix composite, cermet, or semiconductor.

23. The apparatus of claim 18, wherein the first wafer, second wafer, and shim layer are bonded together with a cryogenic-grade epoxy.

24. The apparatus of claim 18, wherein the detector portion of the detector array is not disposed on a transparent substrate.

25. An apparatus for accommodating CTE mismatch in microelectronic or optoelectronic components where a module has different CTE than its immediate substrate by creating a balanced stack with a configurable composite average CTE as a substrate material, the method comprising:
a first wafer of a first material and a first thickness;
a second wafer of a third material and a third thickness;
a shim layer of a second material and a second thickness;
wherein the first wafer, second wafer, and shim layer are bonded together to form a balanced wafer stack having a specified composite average CTE, wherein the composite average CTE is determined by the relative thicknesses of the wafers and the shim layer, and also by the compositions of the wafers and shim layer, and wherein the shim layer is disposed between the wafers; and
further wherein the wafer stack is diced into individual balanced stack dies suitable for further fabrication processing or hybridization.

26. The apparatus of claim 25, wherein the first wafer, second wafer, and shim layer are bonded together simultaneously.

27. The apparatus of claim 25, said second material comprising a metal, ceramic, polymer, metal matrix composite, cermet, or semiconductor.

28. The apparatus of claim 25, wherein the first wafer, second wafer, and shim layer are bonded together with at least one of: bonding with adhesive, fusion bonding, anodic bonding, and intermediate layer bonding.

29. The apparatus of claim 25, said first material comprising a semiconductor, ceramic, or polymer.

30. The apparatus of claim 25, said third material comprising a semiconductor, ceramic, or polymer.
